(19) United States
(12) Patent Application Publication
(10) Pub. No.: US 2007/0280014 A1
(43) Pub. Date: Dec. 6, 2007

(54) Semiconductor device

(76) Inventor: Hiroyuki Sekiguchi, Kanagawa (JP)

Correspondence Address: MCDERMOTT WILL & EMERY LLP, 600 13TH STREET, NW, WASHINGTON, DC, 20005-3096, US

(21) Appl. No.: 11/806,122

(22) Filed: May 30, 2007

(30) Foreign Application Priority Data
May 30, 2006 (JP) P. 2006-149955

(51) Int. Cl. G11C 29/00; G11C 7/00

(52) U.S. Cl. 365/200

(57) ABSTRACT

A semiconductor device having a self test function includes a memory, a first data processing portion connected to a former stage of the memory through a first path, a second data processing portion connected to a latter stage of the memory through a second path, a failure detecting circuit for detecting a failure of the first data processing portion, the first path, the memory, the second path and the data processing portion by using a test pattern, a normal path provided on an input side of the first data processing portion and serving to transmit a signal to the first data processing portion in a normal operation of the semiconductor device, a first test path provided on the input side of the first data processing portion and serving to transmit a test pattern output from the failure detecting circuit in a test operation of the semiconductor device, and a selecting and output portion for selecting either a signal input through the normal path or a signal input through the first test path and outputting the same signal to the first data processing portion.

### BACKGROUND OF THE INVENTION

1. Field of the Invention

The present invention relates to a semiconductor device for detecting a failure of a path connected to a memory and a data processing portion in addition to a failure of the memory.

2. Description of the Related Art

With an enhancement in an integration and an increase in a speed of a semiconductor device, an increase in a fineness of a transistor and a wiring has been rapidly advanced. When a manufacturing process is made finer, however, a variation in the process or a failure caused by a slight defect generated in a manufacture might be made. For this reason, BIST (Built-In Self Test) has been utilized as a test method for guaranteeing an actual operation.

For example, an LSI comprising a memory and a path and having a self test function includes a memory BIST circuit. FIG. 2 shows an example of the LSI. The LSI shown in FIG. 2 comprises a memory 11, normal paths 12a and 12b, flip-flops 13a and 13b, logic circuits 14a and 14b, a memory BIST circuit 15, a selector 16, and test paths 17a and 17b.

The flip-flop 13a and the logic circuit 14a are provided in a former stage of the memory 11. Data input to the flip-flop 13a and processed in the logic circuit 14a in a normal operation of the LSI are transmitted to the memory 11 through the normal path 12a and the selector 16. Moreover, the flip-flop 13b and the logic circuit 14b are provided in a latter stage of the memory 11. The data output from the memory 11 in the normal operation of the LSI are transmitted through the normal path 12b and are input to the logic circuit 14b, and are processed in the logic circuit 14b and are then output from the flip-flop 13b.

The selector 16 outputs, to the memory 11, either a signal input through the normal path 12a or a signal output from the memory BIST circuit 15 and input through the test path 17a. The selector 16 outputs the signal input through the normal path 12a in the normal operation of the LSI and outputs the signal input through the test path 17a in a test operation of the LSI.

In the LSI carrying out a self test, the memory BIST circuit 15 outputs a test pattern. The test pattern is transmitted through the test path 17a and is written to the memory 11 through the selector 16. Next, the memory BIST circuit 15 reads the test pattern from the memory 11 through the test path 17b. The memory BIST circuit 15 compares the test pattern thus read with an expected value and thus detects a failure of the memory 11.
Patent Document 1: JP-A-6-67919 Publication
Patent Document 2: JP-A-2000-99557 Publication

However, the LSI described above can detect the failure of the memory 11 and cannot detect the failure of the normal paths 12a and 12b, the flip-flops 13a and 13b, and the logic circuits 14a and 14b. In the LSI, a method using a different function pattern from the test pattern is required for detecting the failure of the normal paths 12a and 12b, the flip-flops 13a and 13b and the logic circuits 14a and 14b. The generation of the function pattern causes an increase in a man-hour and a prolongation of a development period of the LSI.

If the LSI is complicated, moreover, it is hard to carry out sufficient screening by only a degenerate failure test. Therefore, the screening at an actual speed is essential. For this reason, an actual speed scan test intended for detecting a delay failure is carried out. However, the LSI cannot carry out the actual speed scan test for the normal paths 12a and 12b, the flip-flops 13a and 13b, and the logic circuits 14a and 14b.

### SUMMARY OF THE INVENTION

It is an object of the invention to provide a semiconductor device capable of detecting a failure of a path connected to a memory and a data processing portion in addition to a failure of the memory.

The invention provides a semiconductor device having a self test function, comprising a memory for storing data, a first data processing portion connected to a former stage of the memory through a first path for transmitting a signal, a second data processing portion connected to a latter stage of the memory through a second path for transmitting a signal, a failure detecting circuit for detecting a failure of the first data processing portion, the first path, the memory, the second path and the data processing portion by using a test pattern, a normal path provided on an input side of the first data processing portion and serving to transmit a signal to the first data processing portion in a normal operation of the semiconductor device, a first test path provided on the input side of the first data processing portion and serving to transmit the test pattern output from the failure detecting circuit in a test operation of the semiconductor device, and a selecting and output portion for selecting either a signal input through the normal path or a signal input through the first test path and outputting the same signal to the first data processing portion.

In the semiconductor device, the first data processing portion includes a flip-flop to which the signal output from the selecting and output portion is input.

In the semiconductor device, the data read from the memory are transmitted to the failure detecting circuit through the second path and the second data processing portion, and a second test path for transmitting a signal in the test operation of the semiconductor device.

In the semiconductor device, the second data processing portion includes a flip-flop for outputting the data read from the memory to the second test path.

In the semiconductor device, the failure detecting circuit detects a delay failure.

According to the semiconductor device in accordance with the invention, it is possible to detect the failure of the path connected to the memory and the data processing portion in addition to the failure of the memory.

### BRIEF DESCRIPTION OF THE DRAWINGS

FIG. 1 is a block diagram showing a structure of a semiconductor device according to an embodiment, and

FIG. 2 is a block diagram showing a structure of a conventional semiconductor device.

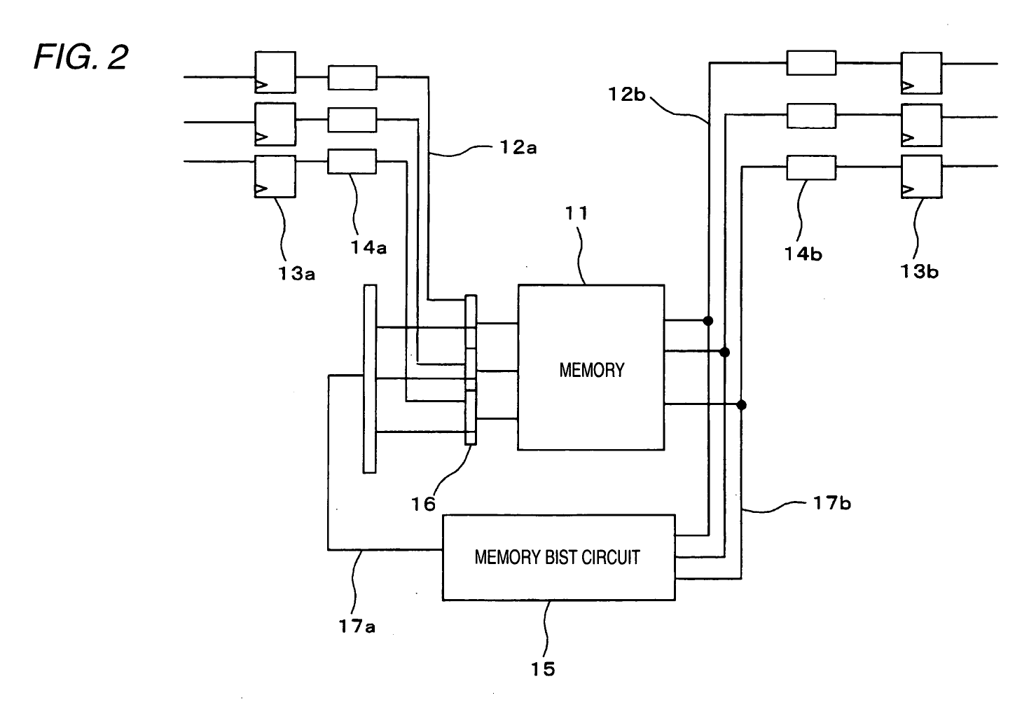

### DESCRIPTION OF THE PREFERRED EMBODIMENTS

An embodiment according to the invention will be described below with reference to the drawings.

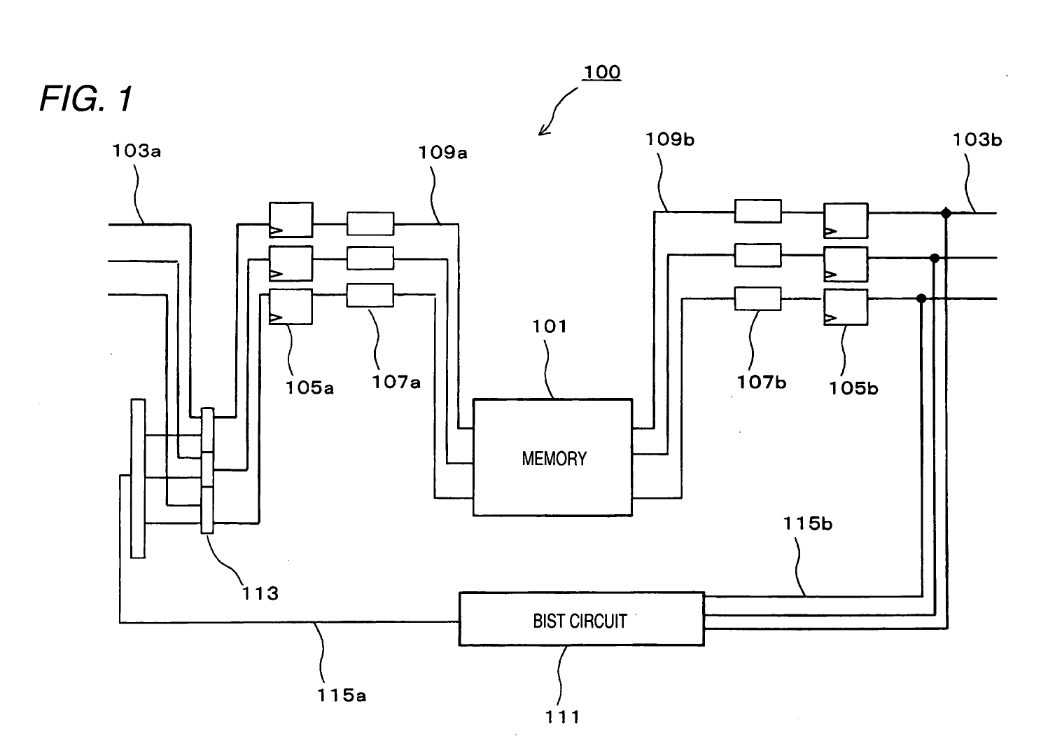

FIG. 1 is a block diagram showing a structure of a semiconductor device according to an embodiment. A semiconductor device 100 shown in FIG. 1 comprises a memory 101, normal paths 103a and 103b, flip-flops 105a and 105b, logic circuits 107a and 107b, common paths 109a and 109b, a BIST circuit 111, a selector 113, and test paths 115a and 115b, and has a self test function.

The flip-flop 105a and the logic circuit 107a are provided in a former stage of the memory 101. Data transmitted through the normal path 103a or data transmitted through the test path 115a are input to the flip-flop 105a through the selector 113. The data output from the flip-flop 105a and processed in the logic circuit 107a are transmitted through the common path 109a and are input to the memory 101.

The flip-flop 105b and the logic circuit 107b are provided in a latter stage of the memory 101. The data output from the memory 101 are transmitted through the common path 109b and are input to the flip-flop 105b. The data output from the flip-flop 105b and processed in the logic circuit 107b are transmitted through the normal path 103b and the test path 115b.

The selector 113 outputs, to the logic circuit 107a, either a signal input through the normal path 103a or a signal output from the BIST circuit 111 and input through the test path 115a. The selector 113 outputs the signal input through the normal path 103a in a normal operation of the semiconductor device 100 and outputs the signal input through the test path 115a in a test operation of the semiconductor device 100.

In the semiconductor device 100 to carry out a self test, the BIST circuit 111 outputs a test pattern for an actual speed scan test. The test pattern is transmitted through the test path 115a and is written to the memory 101 through the selector 113, the flip-flop 105a, the logic circuit 107a and the common path 109a. Next, the BIST circuit 111 reads the test pattern from the memory 101. At this time, the test pattern read from the memory 101 is transmitted to the BIST circuit 111 through the common path 109b, the logic circuit 107b, the flip-flop 105b and the test path 115b. The BIST circuit 111 compares the test pattern thus read with an expected value, thereby detecting a delay failure of the flip-flops 105a and 105b, the logic circuits 107a and 107b, the common paths 109a and 109b, and the memory 101.

As described above, in the semiconductor device 100 according to the embodiment, the selector 113 is positioned on an input side of the flip-flop 105a provided in the former stage of the memory 101. Moreover, the test pattern read from the memory 101 is transmitted to the BIST circuit 111 through the common path 109b, the flip-flop 105b and the logic circuit 107b which are provided in the latter stage of the memory 101. Therefore, the semiconductor device 100 can detect a delay failure generated in the flip-flops 105a and 105b, the logic circuits 107a and 107b, and the common paths 109a and 109b in addition to the delay failure of the memory 101. For this reason, it is possible to carry out screening corresponding to a result of the actual speed scan test.

Moreover, a circuit area is not increased as compared with the conventional structure. Therefore, it is possible to suppress an increase in a test cost. Furthermore, the semiconductor device 100 according to the embodiment can also be applied to an LSI which does not have a processor such as a CPU.

While the description has been given on the assumption that the BIST circuit 111 detects the delay failure in the embodiment, it is also possible to detect failures such as a degenerate failure, an open failure and a bridge failure.

The semiconductor device according to the invention is useful as an LSI for detecting a failure of the path connected to the memory and the data processing portion in addition to a failure of the memory.

What is claimed is:

1. A semiconductor device having a self test function, comprising:
a memory for storing data;
a first data processing portion connected to a former stage of the memory through a first path for transmitting a signal;
a second data processing portion connected to a latter stage of the memory through a second path for transmitting a signal;
a failure detecting circuit for detecting a failure of the first data processing portion, the first path, the memory, the second path and the data processing portion by using a test pattern;
a normal path provided on an input side of the first data processing portion and serving to transmit a signal to the first data processing portion in a normal operation of the semiconductor device;
a first test path provided on the input side of the first data processing portion and serving to transmit the test pattern output from the failure detecting circuit in a test operation of the semiconductor device; and
a selecting and output portion for selecting either a signal input through the normal path or a signal input through the first test path and outputting the same signal to the first data processing portion.

2. The semiconductor device according to claim 1, wherein the first data processing portion includes a flip-flop to which the signal output from the selecting and output portion is input.

3. The semiconductor device according to claim 1, wherein the data read from the memory are transmitted to the failure detecting circuit through the second path and the second data processing portion, and a second test path for transmitting a signal in the test operation of the semiconductor device.

4. The semiconductor device according to claim 3, wherein the second data processing portion includes a flip-flop for outputting the data read from the memory to the second test path.

5. The semiconductor device according to claim 1, wherein the failure detecting circuit detects a delay failure.
